(19) United States
(12) Patent Application Publication
(10) Pub. No.: US 2013/0153010 A1
(43) Pub. Date: Jun. 20, 2013

(54) COMBUSTOR FOR THERMOPHOTOVOLTAIC POWER SYSTEMS

(71) Applicants: YUEH-HENG LI, TAINAN CITY (TW); GUAN-BANG CHEN, TAINAN CITY (TW); YEI-CHIN CHAO, TAINAN CITY (TW); TSARNG-SHENG CHENG, TAINAN CITY (TW); CHIH-YUNG WU, TAINAN CITY (TW)

(72) Inventors: YUEH-HENG LI, TAINAN CITY (TW); GUAN-BANG CHEN, TAINAN CITY (TW); YEI-CHIN CHAO, TAINAN CITY (TW); TSARNG-SHENG CHENG, TAINAN CITY (TW); CHIH-YUNG WU, TAINAN CITY (TW)

(73) Assignee: NATIONAL CHENG KUNG UNIVERSITY, TAINAN CITY (TW)

(21) Appl. No.: 13/466,396

(22) Filed: May 8, 2012

(30) Foreign Application Priority Data
Dec. 16, 2011 (TW) 100146780

(51) Int. Cl. H01L 31/02

(52) U.S. Cl. 136/253

(57) ABSTRACT

A combustor for thermaophotovoltaic power systems includes a chamber body pervious to light and a metal porous medium as well as an emitter tube disposed inside the chamber body, respectively. By using a mixed liquid fuel to penetrate through the porous medium to form a fuel-film on the surface thereof and injecting the air into the chamber body, the contact surface of the fuel and the air is increased for promoting the thermal conduction and thoroughly vaporizing the liquid fuel to attain the flame stabilization. Further, the material of metal carbonyl can be added into the liquid fuel to efficiently increase the intensity of the flame luminescence after the burning reaction, and the radiation of the emitter tube combines with the radiation of the flame luminescence to increase the luminosity and enhance the electricity conversion efficiency.

### BACKGROUND OF THE INVENTION

1. Field of the Invention

The present invention relates to a combustor, more particularly a combustor applied to thermophotovoltaic power systems.

2. Description of the Related Art

Recently, the development of various electronic products such as notebooks, cellular phones, PDAs, Digital cameras, DVs, GPS, etc. has brought about an enormous market, and those electronic products almost become necessaries nowadays. The consequence attendant on the large amount of electronic products is to raise great demand for electricity and related energy supply devices.

The conventional electricity supply device mainly uses the chemical reaction induced by two electrodes and the electrolyte to convert the chemical energy of batteries into electricity. However, since the battery has limited storage of energy, the development of fuel cells becomes a trend at present. For example, concerning the energy density within the popular lithium battery under 10% overall efficiency, the lithium battery has the energy storage that is at best only less than 0.01 times the energy density created by the generating system of hydrocarbon fuels. Thus, hydrocarbon fuels are frequently used as the energy source to supply electricity. Prior references as disclosed in Taiwan Patent number 1226722 and Patent number 00551536 are directed to the combustion of hydrocarbon fuels for converting the thermal energy into the electricity so as to develop a thermophotovoltaic (TPV) power system, based on transmitting the chemical energy into the light via an emitter and then converting the light into electricity via a PV cell.

In practical, it is difficult to apply the TPV power system to a small-scale combustion system. Such a combustor system with reduced physical dimension usually shortens the residence time of fuel and air and leads to a poor fuel/air mixing as well as incomplete combustion. Further, heat from the combustion is generated volumetrically and easily gets lost through the surface. In other words, miniaturizing a combustor size may cause the problems such as heat loss to the surroundings, flame quenching and poor combustion efficiency. For solving the above problems, some improvements, including the use of high inflammable hydrogen or catalyst medium as fuels or the combination with a heat recirculation system to resist the heat loss, may be adopted, but all of which still limit the combustion effect of the small-scale combustion system. In addition, it also fails to attain the complete combustion due to the shortened residence time of fuel and air and the poor fuel/air mixing, which thence results in the poor radiation of the emitter and reduces the efficiency of electricity conversion.

### SUMMARY OF THE INVENTION

The object of the present invention is to provide a combustor applied to thermophotovoltaic power systems to increase the combustion efficiency and attain the flame stabilization, thereby attaining a high-luminescence flame and emitting radiation to promote the electricity conversion.

In order to achieve the above object, the combustor for thermophotovoltaic power systems in accordance with the present invention includes a chamber body pervious to light and a porous medium as well as an emitter tube respectively disposed inside the chamber body. Wherein, the emitter tube is disposed above the porous medium, and the porous medium is made of a metal material which allows a mixed liquid fuel to penetrate therethrough. Further, the chamber body has a chamber room defined therein, a fuel inlet port connecting to the porous medium and allowing an introduction of the mixed liquid fuel, and an air inlet port communicating with the chamber room and allowing an entry of air. The liquid fuel penetrates through the porous medium to form a fuel-film. Accordingly, the air swirls in the chamber room of the chamber body when the liquid fuel penetrates the surface of the porous medium for combustion, which makes the contact surface of the fuel and the air increase for promoting the thermal conduction and thoroughly vaporizing the liquid fuel to attain the flame stabilization. Preferably, the material of metal carbonyl can be added into the liquid fuel to efficiently enhance the intensity of the flame luminescence, and the radiation of the emitter tube combines the radiation of the flame luminescence to efficiently increase the flame luminosity, thereby promoting the electricity conversion efficiency.

Preferably, the mixed liquid fuel is made by mixing liquid hydrocarbon fuels and metal carbonyl.

Preferably, the chamber body is made of quartz.

Preferably, the metal porous medium is formed into a conical shape.

Preferably, the emitter tube is made of silicon carbide.

The advantages of the present invention over the known prior arts will become more apparent to those of ordinary skilled in the art upon reading the following descriptions in junction with the accompanying drawings.

### BRIEF DESCRIPTION OF THE DRAWINGS

Exemplary embodiments of the invention are explained in the following with reference to drawings. The patent or application file contains at least one drawing executed in color. Copies of this patent or patent application publication with color drawings will be provided by the Office upon request and payment of the necessary fee.

FIG. 1 is a schematic view showing a preferred embodiment of the present invention;

FIG. 2 is a schematic view showing a spectrum distribution of flame luminosity, emitter radiation and flame luminosity coupling with the emitter radiation; and

FIG. 3 is a schematic view showing photos of the combustion chamber operating with an emitter tube for (a) pure n-Heptane, (b) n-Heptane plus 0.2 vol. % iron pentacarbonyl at 15 mg/s and an equivalence ratio of 1.2 when the distance between the porous medium and the emitter tube is approximately 15 mm.

### DETAILED DESCRIPTION OF THE PREFERRED EMBODIMENTS

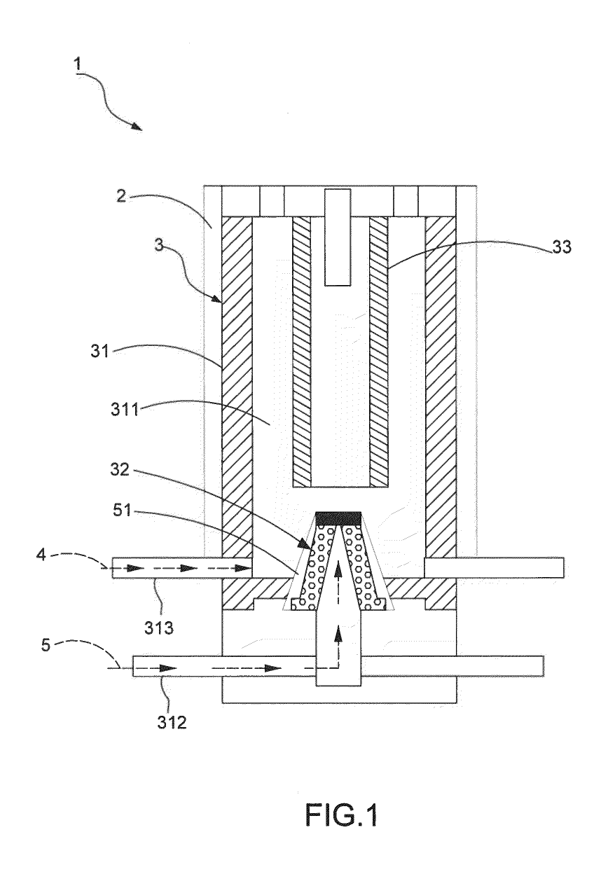

FIG. 1 shows a combustor 3 for thermophotovoltaic power systems 1 of a first preferred embodiment. The thermophotovoltaic power system 1 includes a combustor 3 and a photovoltaic cell array 2 disposed in relation to the combustor 3. Wherein, the combustor 3 comprises a chamber body 31 pervious to light and a porous medium 32 as well as an emitter tube 33 disposed inside the chamber body 31, respectively. The emitter tube 33 is disposed above the porous medium 32, and the porous medium 32 is made of a metal material which allows a mixed liquid fuel 5 to penetrate therethrough. Regarding to the mixed liquid fuel 5 as claimed, the liquid fuel 5 can be made by mixing liquid hydrocarbon fuels and metal carbonyl, especially in this preferred embodiment, the liquid fuel 5 of the present invention mainly mixes the liquid hydrocarbon fuels such as n-Heptane, pentane, etc. with the metal carbonyl such as iron pentacarbonyl, so that the mixed liquid fuel 5 can be used to adjust the flame luminosity in light of the adding proportion of the iron pentacarbonyl. Furthermore, the porous medium 32 can be made of the metal material such as bronze or stainless steel, and the bronze is described as an example. The pore size of the porous medium 32 is adjustable to increase the fuel-air contact surface and the thermal conduction, thereby facilitating the vaporization of the liquid fuel 5. The metal porous medium 32 can be formed into any appropriate shape such as a column shape, conical shape, etc., and the conical shape is adopted in the preferred embodiment. Also in the preferred embodiment, the emitter tube 33 disposed above the porous medium 32 can be made of a silicon carbide or other proper materials, and the emitter tube 33 and the porous medium 32 are disposed to be spaced apart, preferably spaced 15 cm apart, so that the flame congregates between the porous medium 32 and the emitter tube 33 to efficiently heat the emitter tube 33.

Still further, the chamber body 32 is made of a material pervious to light, like quartz, glass, or other suitable materials, and the quartz material is herein adopted. The chamber body 31 has a chamber room 311 defined therein, a fuel inlet port 312 connecting to the porous medium 32 and allowing an introduction of the mixed liquid fuel 5, and an air inlet port 313 communicating with the chamber room 311 and allowing an entry of air 4. The liquid fuel 5 penetrates through the porous medium 32 to form a fuel-film 51 while injecting the air 4 into the chamber body 31, so that the luminous radiation of the flame luminescence generated by the combustion of the liquid fuel 5 and an emitter incandescence brought about by heating the emitter tube 33 are combined to be emanated from the chamber body 31 toward the photovoltaic cell array 2 for being converted into electricity.

Referring to FIG. 1, while in operation, the emitter tube 33 operates in the temperature range from 1,000 to 1,600 K. The air 4, supplied by an air compressor and metered by an electronic flowmeter (not shown), is injected tangentially from the air inlet port 313 into the chamber room 311. At the same time, the mixed liquid fuel 5 is also injected from the fuel inlet port 312 for the liquid fuel 5 to become combustible inside the chamber body 31 and create a flame sheet (not shown). By means of the fuel-film 51 formed on the surface of the porous medium 32 while penetrating the liquid fuel 5 through the metal porous medium 32, the vaporized surface of the liquid fuel 5 increases to absorb the heat from the flame sheet, thereby attaining the effect of heat recuperation. Therefore, the porous medium 32 assists in vaporizing the liquid fuel 5 and increasing the fuel/air mixing efficiency as well as the thermal conduction. The air 4 is tangentially injected to induce a swirling effect for the flame base of the flame sheet to be anchored at the lateral surface of the porous medium 32 while burning the liquid fuel 5, so as to attain the effect of flame stabilization.

During the burning of the liquid fuel 5, the operation of the fuel may affect the upper limit and the low limit of the porous medium 32. The upper limit defines the flame quenching while the low limit is determined by dry-out-and -replenishment instability. Because the liquid fuel 5 is made of the mixing of liquid hydrocarbon fuels such as n-Heptane and metal carbonyl such as iron pentacarbonyl, the addition of iron pentacarbonyl reduces the low limit of the metal porous medium 32 and allows a latent heat of the vaporization of the present liquid fuel 5 to be lower than that of the pure hydrocarbon fuel. In this manner, the flame velocity of the liquid fuel 5 is reduced to increase the flame temperature as well as the intensity of the flame luminescence. Further, by means of the emitter tube 33 disposed inside the chamber body 31 and the space arrangement between the emitter tube 33 and the porous medium 32, the luminescence of the flame sheet congregates between the porous medium 32 and the emitter tube 33, and the flame sheet burns along the wall of the emitter tube 33, which efficiently increases the surface temperature and the radiation incandescence and intensity of the emitter tube 33 so as to highly increase the flame luminosity. The emitter incandescence of emitter tube 33 further combines with the radiation of the flame luminescence and the combined radiation is transmitted from the quartz chamber body 31 to the photovoltaic cell array 2, whereby the photovoltaic cell array 2 can efficiently convert the radiation into electricity for use.

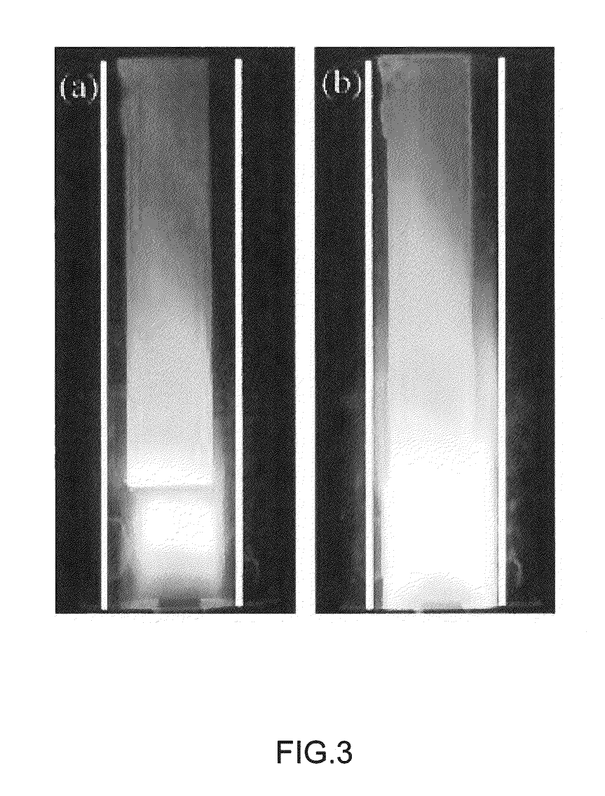

To show that the increased intensity of the flame luminescence is preferably attained as a result of the liquid fuel 5 mixed with an addition of metal carbonyl and the specific arrangement of the emitter tube 33 and the metal porous medium 32, the present invention makes an combustion experiment in which a pure hydrocarbon fuel (n-Heptane) and a n-Heptane mixed with 0.2% Iron pentacarbonyl under the equivalence ratio of 1.2 are used as two respective liquid fuels 5. Further, the porous medium 32 and the emitter tube 33 are 15 mm spaced apart. In the experiment, the intensity from the combustor 3 with pure n-Heptane flame is about 22 nW/mm² (see FIG. 3(a)), which is much lower than the mixing of n-Heptane and iron pentacarbonyl flame whose intensity is significantly enhanced by fivefold and ranged approximately 125 nW/mm² as shown in FIG. 3(b)). It shows that the mixed liquid fuel 5 decreases the low limit of the porous medium 32 to make the fuel combustible and increase the flame temperature and luminescence. The flame color of the iron pentacarbonyl flame even turns to silver white (see FIG. 3(b)) and burns along the emitter tube 33 to efficiently increase the temperature of the emitter tube 33. The radiation of the flame luminescence and the emitter radiation of the emitter tube 33 are grouped to enhance the flame luminosity. Therefore, by adding the mixed liquid fuel 5, the present invention efficiently promotes the intensity of the flame luminescence and flame luminosity.

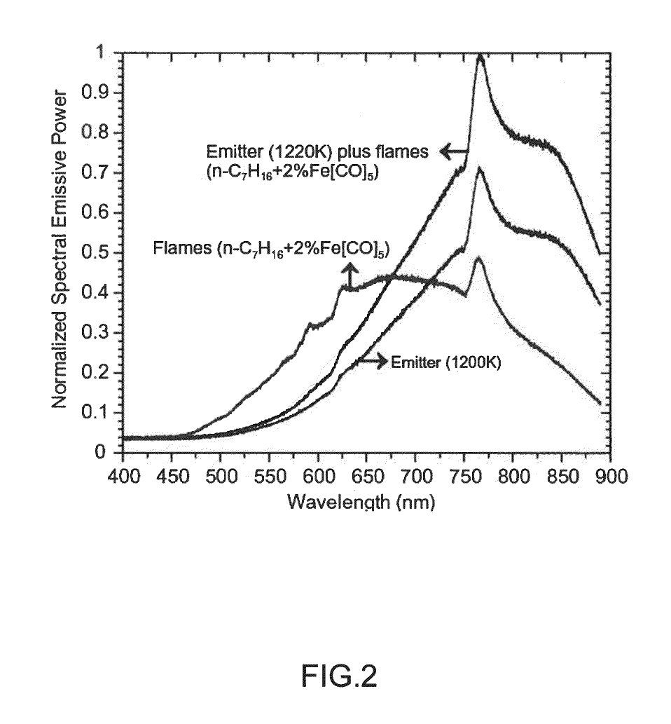

When the flame luminosity is enhanced and the surface emitter radiation is also increased due to the increased temperature of the 1 emitter tube 33, the present invention further utilizes a spectrometer to measure the spectrum of the present combustor 3. The result as shown in FIG. 2 indicates that the wavelength of the radiation from the cooperation of the mixed liquid fuel 5 and the emitter tube 33 are located from a visible range to a near infrared range. With respect to the radiant intensity, by comparing the present invention with the single radiation of the emitter tube 33, the combustor 3 with the adding of iron pentacarbonyl into the liquid fuel 5 and the emitter tube 33 increases not only the intensity of the flame luminescence but the emitter incandescence, in particularly the flame intensity in the visible range is largely increased and the emitter tube 33 in higher temperature enhances the infrared range of the radiation intensity. Therefore, the electricity conversion of the photovoltaic cell array 2 is increased.

As a result, the present invention has the following advantages:

1. By adding the metal carbonyl into the liquid fuel, the present invention attains to adjust the intensity of the flame luminescence. While combining the radiation of the flame luminescence with the emitter radiation, the flame luminosity of the present combustor is increased to attain a high-luminescence flame, facilitating the electricity conversion of the photovoltaic cell array.
2. The liquid fuel penetrates through the porous medium to form a liquid fuel-film on the surface thereof, which increases the contact surface of the liquid fuel and the heat recuperation from the flame to efficiently vaporize the liquid fuel and promote the fuel/air mixing efficiency and the thermal conduction. The air is tangentially injected to induce a swirling effect for the flame base to be anchored at the lateral surface of the porous medium while burning the liquid fuel, which facilitates an effect of flame stabilization.

To sum up, the present invention takes advantage of the formation of a liquid fuel-film on the surface of the porous medium to increase the fuel/air contact surface and thermal conduction and fully vaporize the liquid fuel under an injection of swirling air, thereby attaining the flame stabilization. Further, the material of metal carbonyl is added into the liquid fuel to efficiently increase the intensity of the flame luminescence. The combination of the radiation of the flame luminescence with the emitting radiation of the emitter tube promotes the flame luminosity, so the present invention provides the high-luminescence flame to promote the following electricity conversion efficiency.

While the present invention has been described in its preferred embodiments, it is understood that the afore description has been given only by way of example and that numerous changes in the details of construction, fabrication and use to make further variations, alternatives and modifications, including the combination and arrangement of parts, may be made without departing from the scope of the present invention.

What is claimed is:

1. A combustor for said thermophotovoltaic power systems, said thermophotovoltaic power systems includes a combustor and a photovoltaic: ceil array disposed in relation to said combust or;
wherein said combustor comprises a chamber body made of a material pervious to light and a porous medium as well as an emitter tube respectively disposed inside said chamber body; said emitter tube being disposed above said porous medium, and said porous medium being made of a metal material which allows a mixed liquid fuel to penetrate therethrough, said chamber body having a chamber room defined therein, a fuel inlet port connecting to said porous medium and allowing an introduction of said mixed liquid fuel, and an air inlet port communicating with said chamber room and allowing an entry of air, said liquid fuel penetrating through said porous medium to form a fuel-film while injecting said air into said chamber body so that a radiation of flame luminescence generated by burning said liquid fuel and an emitter incandescence brought about by heating said emitter tube are emanated from said chamber body to said photovoltaic cell array for converting said radiation into electricity.

2. The combustor as claimed in claim 1, wherein said mixed liquid fuel is made by mixing liquid hydrocarbon fuels and metal carbonyl,

3. The combustor as claimed in claim 1, wherein said, chamber body is made of quartz.

4. The combustor as claimed in claim 2, wherein said chamber body is made of quartz.

5. The combustor as claimed, in claim 1, wherein said metal porous medium is formed into a conical shape,

6. The combustor as claimed in claim 2, wherein said metal porous medium is formed into a conical shape.

7. The combustor as claimed in claim 1, wherein said emitter tube is made of silicon carbide,

8. The combustor as claimed in claim 2, wherein said emitter tube is made of silicon carbide.
